(19) United States
(12) Patent Application Publication
(10) Pub. No.: US 2012/0251428 A1
(43) Pub. Date: Oct. 4, 2012

(54) CRYSTAL GROWING APPARATUS, METHOD FOR MANUFACTURING NITRIDE COMPOUND SEMICONDUCTOR CRYSTAL, AND NITRIDE COMPOUND SEMICONDUCTOR CRYSTAL

(76) Inventor: Satoru Morioka, Toda-shi (JP)

(21) Appl. No.: 13/515,714

(22) PCT Filed: Mar. 3, 2011
(86) PCT No.: PCT/JP2011/054902

§ 371 Date: Jun. 13, 2012

(30) Foreign Application Priority Data
Mar. 4, 2010 (JP) 2010-047331

(51) Int. Cl. C30B 25/10; C01B 21/00; C30B 25/14

(52) U.S. Cl. 423/351; 118/725; 117/88

(57) ABSTRACT

Disclosed is a crystal growing apparatus, which is useful when growing a nitride semiconductor crystal by means of hydride vapor phase deposition, and which is capable of effectively preventing a reaction tube from breaking, and is capable of growing the high quality nitride semiconductor single crystal. Also disclosed are a method for manufacturing the nitride compound semiconductor crystal using such crystal growing apparatus, and the nitride compound semiconductor crystal. In the horizontal-type crystal growing apparatus for growing the nitride compound semiconductor crystal on a base substrate using the hydride vapor phase deposition, between the reaction tube (11) end portion (upstream flange (11a)) on the side where raw material gas supply tubes (14, 15) are disposed, and a base substrate disposing position (substrate holder (13)), a plurality of partitioning plates (20) that partition the reaction tube in the axis direction are provided.

### TECHNICAL FIELD

The present invention relates to a crystal growth device for use in growing a nitride-based compound semiconductor crystal by using the hydride vapor phase epitaxy (HVPE), to a production method of the nitride-based compound semiconductor crystal, which uses this crystal growth device, and to the nitride-based compound semiconductor crystal.

### BACKGROUND ART

A semiconductor of a nitride-based compound such as GaN (hereinafter, this is referred to as a GaN-based semiconductor) has excellent characteristics, and is going to be applied in a variety of fields, and researches therefor are actively ongoing. In order to manufacture a GaN-based semiconductor device having excellent characteristics, it is desirable that GaN-based semiconductor single crystal be epitaxially grown on a free-standing GaN substrate (substrate composed only of GaN).

In a vicinity of a melting point of GaN (that is, over 2000° C.), a vapor pressure of nitrogen is extremely high, and it is difficult to grow a GaN crystal by using a melt growth method such as the Czochralski method. Accordingly, in general, the HVPE is used for manufacturing the free-standing GaN substrate.

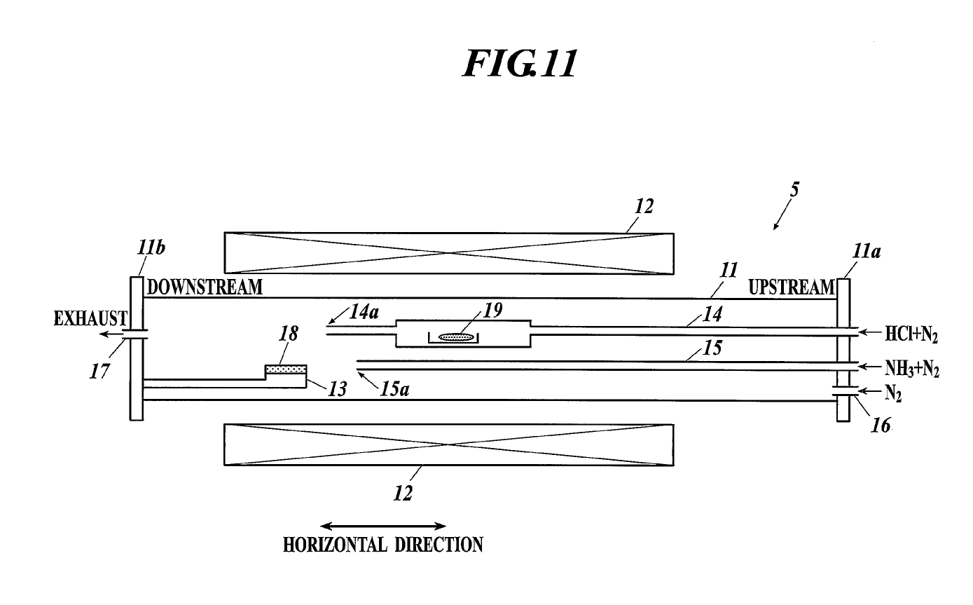

FIG. 11 is a view showing a schematic configuration of a general horizontal-type HVPE device.

As shown in FIG. 11, such a conventional HVPE device 5 includes: a quartz-made reaction tube 11; a heater 12 arranged around the reaction tube 11; a substrate holder 13 that mounts an underlying substrate 18 thereon; a III-group raw material gas supply pipe 14 for supplying III-group raw material gas to a vicinity of the underlying substrate 18; and a V-group raw material gas supply pipe 15 for supplying V-group raw material gas to the vicinity of the underlying substrate 18. Moreover, in a flange 11a on an upstream portion (raw material gas supply side) of the reaction tube 11, a carrier gas introduction port 16 for introducing carrier gas is provided, and in a flange 11b on a downstream side (underlying substrate side) thereof, an exhaust pipe 17 for exhausting residual gas is provided. For the carrier gas, for example, N₂, H₂ or mixed gas of both thereof is used.

In the case of growing the GaN crystal by the HVPE device 5, HCl diluted with the carrier gas is introduced into the III-group raw material gas supply pipe 14, and Ga metal 19 heated at 850° C. and HCl are reacted with each other, whereby GaCl is generated. This GaCl is transported by the III-group raw material gas supply pipe 14, and is supplied as the III-group raw material gas from a nozzle 14a to the vicinity of the underlying substrate 18. Moreover, NH₃ is transported by the V-group raw material gas supply pipe 15, and is supplied as V-group raw material gas from a nozzle 15a to the vicinity of the underlying substrate 18. Gad and NH₃, which are supplied to the vicinity of the underlying substrate 18, are reacted with each other, whereby the GaN crystal is grown on the underlying substrate 18.

At this time, GaN created by reacting GaCl and NH₃ with each other is precipitated not only on the underlying substrate 18 but also on a wall surface of the reaction tube 11. In general, the growth of the GaN crystal is performed in a vicinity of 1000° C. If the reaction tube 11 is cooled to room temperature in a state where GaN is deposited thereon by approximately several hundred micrometers, the reaction tube 11 is cracked and broken owing to a difference in thermal expansion coefficient between GaN and quarts. Accordingly, a protection member made of ceramics or the like is arranged on such portions on which GaN is created, and so on, whereby GaN is prevented from being directly deposited on the wall surface of the reaction tube 11. Moreover, contrivance is made so as to limit a region where such raw material gases are mixed with each other by bringing the introduction ports (nozzles 14a and 15a) of the raw material gasses nearest possible to the underlying substrate 18.

Note that Patent Literatures 1 to 7 describe technologies for arranging baffles (partition plates) in the reaction tube as in the invention of this application; however, do not mention that a backflow of the raw material gases is to be prevented by equalizing a temperature distribution in the reaction tube.

### PRIOR ART DOCUMENTS

### Patent Documents

Patent Document 1: Japanese Examined Patent Application Publication No. H08-18902

Patent Document 2: Japanese Patent Laid-Open Publication No. 2006-225199

Patent Document 3: International Publication WO2006/03367

Patent Document 4: Japanese Patent Laid-Open Publication No. 2004-335559

Patent Document 5: Japanese Patent No. 4116535

Patent Document 6: Japanese Patent No. 4113837

Patent Document 7: Japanese Patent No. 4358646

### DISCLOSURE OF THE INVENTION

### Problem to be Solved by the Invention

As mentioned above, in the conventional HVPE device 5, it is not assumed that GaN is deposited on the wall surface of the upstream portion of the reaction tube 11, and accordingly, the protection member is not arranged on the upstream portion of the reaction tube 11. However, when the GaN crystal was actually grown by using the HVPE device 5, it was proven that GaN was precipitated and deposited on the wall surface of the upstream portion of the reaction tube 11. Since a precipitation amount of GaN on the wall surface of the upstream portion of the reaction tube 11 was small, the reaction tube 11 was not broken soon; however, as the growth of the GaN crystal was being repeated, a deterioration of the reaction tube 11 was gradually observed. That is to say, in the conventional HVPE device 5, there is an apprehension that the reaction tube 11 may be broken during a growing process of the GaN crystal, resulting in a risk that an accident such as gas leakage of the raw material gases may be brought about.

Moreover, when the GaN crystal is grown by using the above-mentioned HVPE device 5, there has been a problem that the grown crystal becomes a black polycrystal.

It is an object of the present invention to provide a crystal growth device, which is useful in growing the GaN-based semiconductor crystal by the hydride vapor phase epitaxy, is capable of effectively preventing the breakage of the reaction tube, and is capable of growing a good-quality GaN-based semiconductor single crystal, to provide a production method of a nitride-based compound semiconductor crystal, which uses this crystal growth device, and to provide the nitride-based compound semiconductor crystal.

### Means for Solving the Problems

The invention described in claim 1 is a horizontal-type crystal growth device, in which,
in a reaction tube, there are arranged:
a substrate holder that holds an underlying substrate;
a raw material gas supply pipe that supplies raw material gas to a vicinity of the underlying substrate; and
a carrier gas introduction port that introduces carrier gas into the reaction tube,
a cylindrical heater that heats the substrate holder and a vicinity of an opening end of the raw material gas supply pipe is arranged around the reaction tube, and
a nitride-based compound semiconductor crystal is grown on the underlying substrate by using hydride vapor phase epitaxy,
wherein a plurality of partition plates which partition the reaction tube in an axial direction are provided between an end portion of the reaction tube on a side where the raw material gas supply pipe is arranged and an installed position of the underlying substrate.

The invention described in claim 2 is the crystal growth device according to claim 1, wherein the plurality of partition plates are notched disks in each of which a part is notched, and are arranged in parallel to one another so that notched portions are located alternately in a vertical direction to form a space in the reaction tube into a meandering shape.

The invention described in claim 3 is the crystal growth device according to claim 2, wherein the plurality of partition plates are arranged at an interval of 1 cm or more to 20 cm or less.

The invention described in claim 4 is the crystal growth device according to claim 2 or 3, wherein the plurality of partition plates excluding a first piece of the plates arranged on an installed position side of the underlying substrate close 60 to 80% of an inner-diameter cross section of the reaction tube.

The invention described in claim 5 is the crystal growth device according to any one of claims 2 to 4, wherein, among the plurality of partition plates, the first piece arranged on the installed position side of the underlying substrate closes less than 50% of the inner-diameter cross section of the reaction tube.

The invention described in claim 6 is the crystal growth device according to any one of claims 1 to 5, wherein the plurality of partition plates are arranged between a spot outside from an upstream side end portion of the heater by a length of 60% of an effective inner diameter of the heater and a spot apart upstream by 10 cm from the installed position of the underlying substrate.

The invention described in claim 7 is a production method of the nitride-based compound semiconductor crystal, wherein the nitride-based compound semiconductor crystal is grown on the underlying substrate by using the crystal growth device according to any one of claims 1 to 6.

The invention described in claim 8 is the production method of the nitride-based compound semiconductor crystal according to claim 7, wherein the underlying substrate is an NGO substrate.

The invention described in claim 9 is the nitride-based compound semiconductor crystal obtained by the production method according to claim 7 or 8,
wherein a polycrystal portion is 25% or less of a whole of a growth area.

A description is made below of a course of completing the present invention.

As shown in FIG. 11, the nozzles 14a and 14b of the raw material gas supply pipes 14 and 15 are guided to approximately a midpoint of the reaction tube 11. In the HVPE device 5 having such a structure, the GaN crystal is precipitated on the wall surface of the upstream portion of the reaction tube 11, and accordingly, the inventors of the present invention have made a guess that the raw material gasses flow back to the upstream portion of the reaction tube 11. Moreover, the inventors of the present invention have thought as follows. The raw material gasses flow back to the upstream portion of the reaction tube 11, an intended supply amount of the raw material gasses and an intended concentration ratio thereof are not realized on the underlying substrate 18, and accordingly, only the black GaN polycrystal grows, and a transparent GaN single crystal cannot be obtained.

### Simulation by Conventional HVPE Device

In this connection, an analysis model obtained by modeling the HVPE device 5 shown in FIG. 11 for analysis was made, a thermal fluid analysis simulation for an inside of the reaction tube was performed, and flows of the gases in the reaction tube were analyzed. Note that, in the analysis model, the introduction port of the N₂ carrier gas is arranged between the III-group raw material gas supply pipe and the V-group raw material gas supply pipe (that is, at a center of the flange).

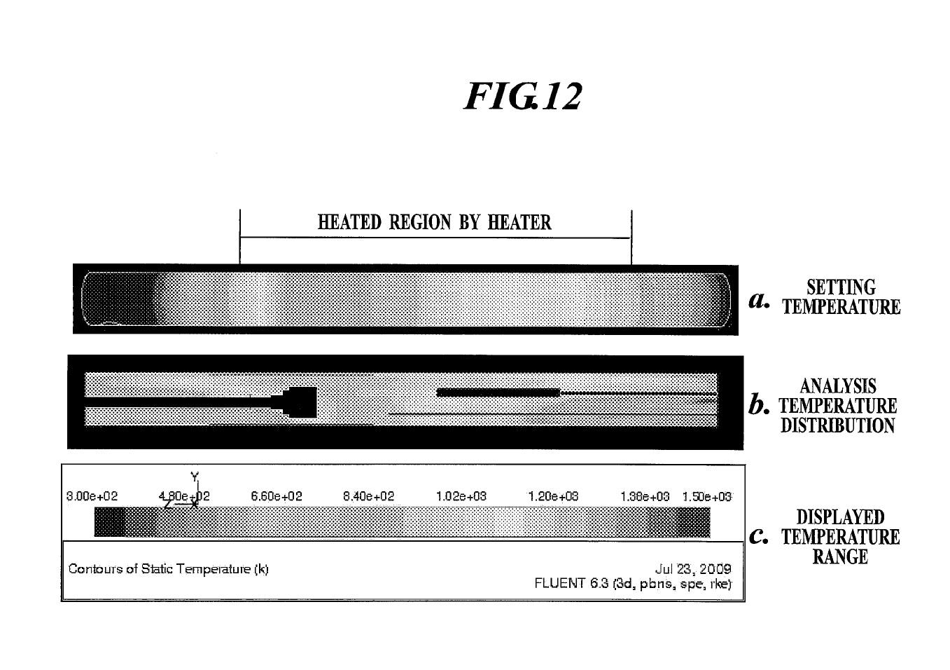

Specifically, supply amounts and supply temperatures of the variety of gases introduced from the carrier gas introduction port 16, the III-group raw material gas supply pipe 14 and the V-group raw material gas supply pipe 15 were set so as to become those of the same conditions as experimental conditions (in Comparative example 1 to be described later), and a temperature of the reaction tube 11 was set as shown in FIG. 12(a).

### Analysis Results of Temperatures

FIG. 12 is a view showing temperature setting of the reaction tube 11 and an analysis result of a temperature distribution in the reaction tube 11. In FIG. 12, longitudinal cross sections of the reaction tube 11, which pass through a center axis thereof, are shown, and this is similarly applied also to analysis results which follow. A displayed temperature range of FIG. 12(c) shows that the temperature is lower on a left gradation, and that the temperature is higher on a right gradation.

As in a setting temperature shown in FIG. 12(a), when the temperature of the reaction tube 11 is low in an outside portion (region other than a heated region) of the heater 12, then such a result was brought also in the inside of the reaction tube 11. That is to say, temperatures of the upstream portion and the downstream portion in the inside of the reaction tube 11 became lower than in a center portion therein, and in particular, a temperature of a lower portion of the reaction tube 11 became low (refer to FIG. 12(b)).

### Analysis Results of Flows

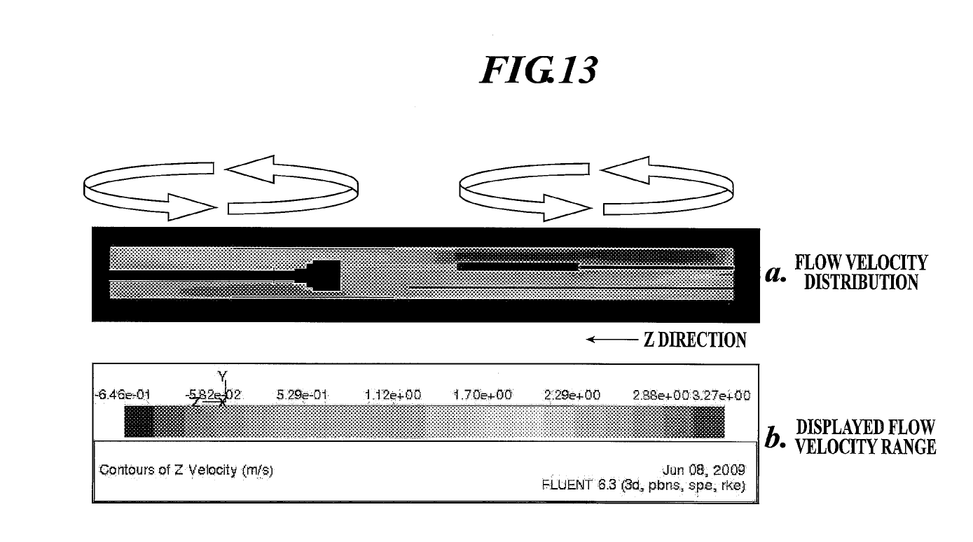

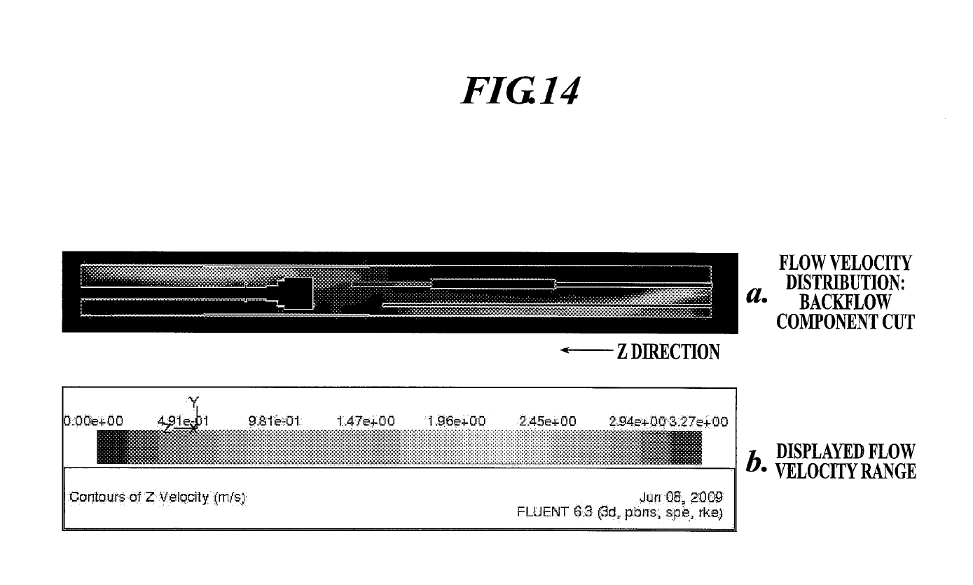

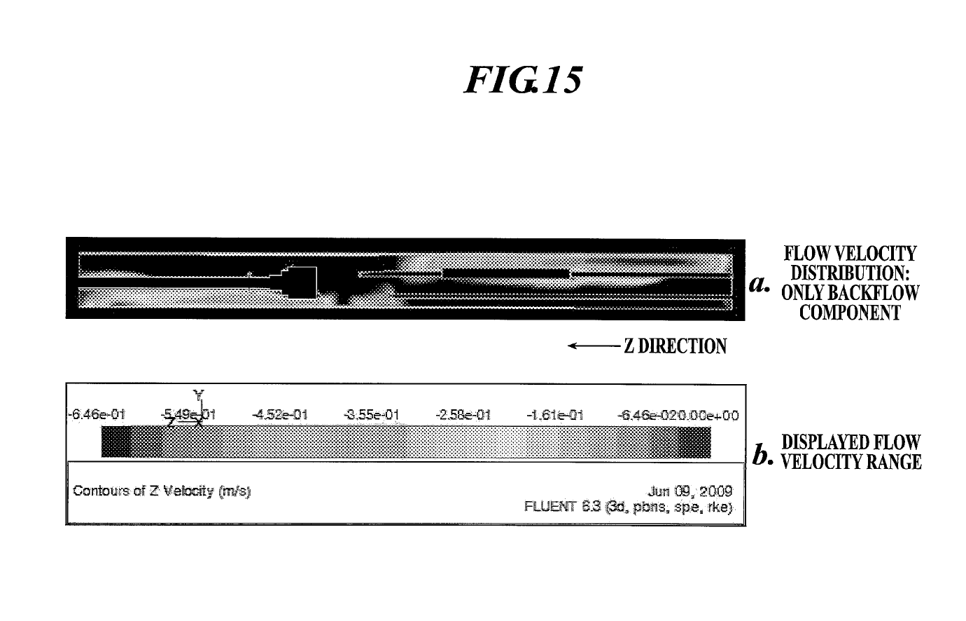

FIGS. 13 to 15 are views showing flow velocity distributions in the Z-direction in the reaction tube 11. In FIG. 14, a backflow component of FIG. 13 is not shown, and in FIG. 15, only the backflow component of FIG. 13 is shown. Here, a direction going from the upstream of the reaction tube 11 toward the downstream thereof is defined as the Z-direction. In FIG. 13 to FIG. 15, portions in which numbers on bars representing displayed flow velocity ranges become negative show that the gas flows back (from the downstream to the upstream). The displayed flow velocity ranges of FIG. 13(b), FIG. 14(b) and FIG. 15(b) show that the flow velocity is slower (or a backflow velocity is faster) on left gradations, and that the flow velocity is faster (or the backflow velocity is slower) on right gradations.

As shown in FIG. 13, there are regions which indicate negative values in an upper portion of the upstream portion of the reaction tube 11 and a lower portion of the downstream portion thereof, which shows a result that the gas flows back at these portions. In detail, results were shown as follows. The N₂ carrier gas that flowed in from the upstream portion flowed into the lower portion of the reaction tube 11, and flowed through the upper portion of the reaction tube 11 in the vicinity of the substrate (refer to FIG. 14), and the gas that flowed back flowed through the upper portion in the upstream portion of the reaction tube 11, and flowed through the lower portion in the downstream portion thereof (refer to FIG. 15).

From these results, it has been found out that there are flows like swirls in the upstream portion and the downstream portion in the reaction tube 11, and that convection occurs. That is to say, it has been expected that the backflow of the raw material gases is caused by the convection in the reaction tube 11, and that this convection is thermal convection owing to a temperature difference between the outside (outside of the heated region) of the heater 12 and the inside (the heated region) thereof.

### Analysis Results of Raw Material Concentration Distributions

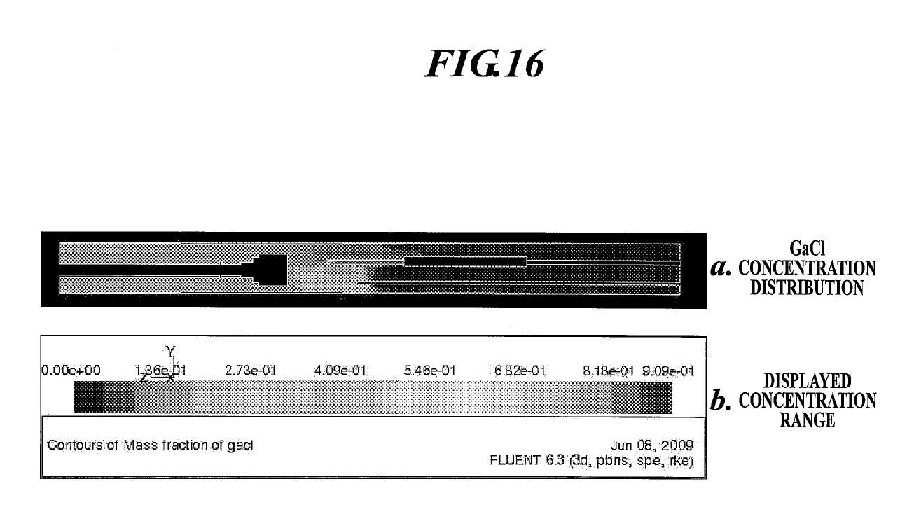

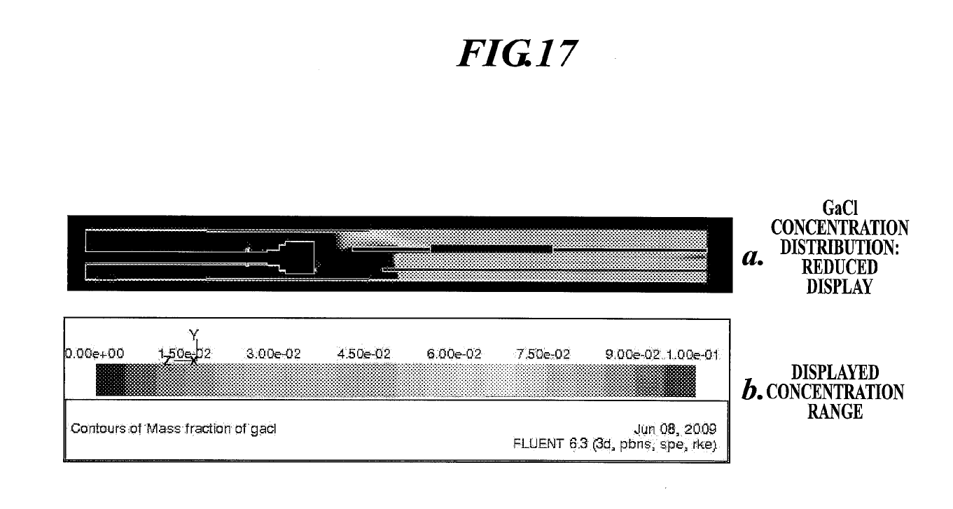

FIGS. 16 and 17 are views showing concentration distributions of GaCl in the reaction tube 11. FIG. 17 shows an analysis result in which a range of a displayed concentration is reduced. Each of displayed concentration ranges of FIG. 16(b) and FIG. 17(b) shows that, while taking a left-end concentration as zero, the concentration is lower on a left gradation, and the concentration is higher on a right gradation.

From FIG. 16, a result was obtained that GaCl was distributed with a high concentration from an outlet of a Ga boat 14b to the nozzle 14a, and was diffused to a vicinity of the substrate holder 13 (that is, the downstream portion of the reaction tube 11). Moreover, it has been found out that GaCl was distributed to the upstream portion of the reaction tube 11 though the concentration thereof was low, and that GaCl flowed back.

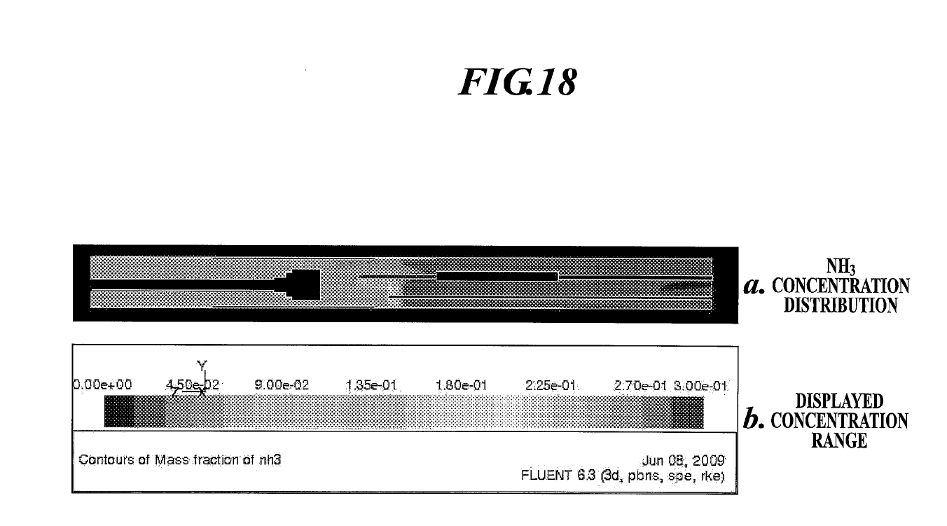

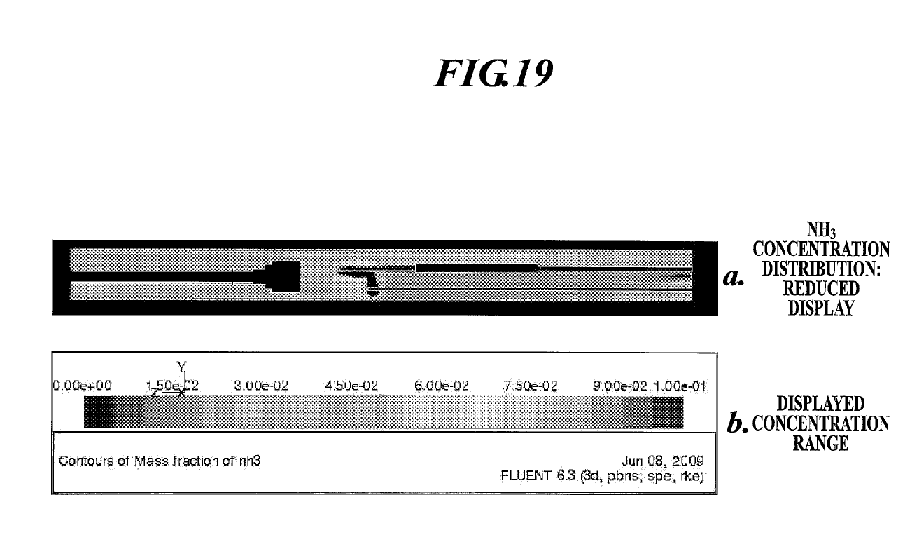

FIGS. 18 and 19 are views showing concentration distributions of NH₃ in the reaction tube 11. FIG. 19 shows an analysis result in which a range of a displayed concentration is reduced. Each of displayed concentration ranges of FIG. 18(b) and FIG. 19(b) shows that, while taking a left-end concentration as zero, the concentration is lower on a left gradation, and the concentration is higher on a right gradation.

From FIGS. 18 and 19, a result was obtained that NH₃ ejected from the nozzle 15a of the V-group raw material gas supply pipe 15 was distributed to the upstream flange 11a of the reaction tube 11.

From these results, it has been found out that the III-group raw material and the V-group raw material are present in the upstream portion of the reaction tube 11. This result shows that GaN is precipitated in the upstream portion of the reaction tube 11, and coincides well with experimental results.

By a further experiment, it has been confirmed that, by the fact that there is a temperature difference between the inside and outside of the heater 12 in the reaction tube 11, the thermal convection occurs in the reaction tube 11, and the raw material gases flow back to the upstream. From this matter, it becomes possible to suppress the raw material gases from flowing back to the upstream portion of the reaction tube 11 if the temperature difference between the inside and outside of the heater 12 in the reaction tube 11 is eliminated. However, it is difficult to heat the outside of the heater 12 in the reaction tube 12.

In this connection, it has been thought out that the temperature distribution in the upstream portion of the reaction tube 11 caused by the N₂ carrier gas lower in temperature than the raw material gases flowing into the reaction tube 11, is to be equalized, to thereby absorb disturbance of the temperature distribution of the upstream portion. Then, it has been invented that baffles (partition plates) are to be arranged in the upstream portion of the reaction tube 11, and in addition, a form (shape, size, arrangement mode) of these partition plates is to be optimized.

### Effect of the Invention

In accordance with the present invention, the temperature distribution in the upstream portion in the reaction tube of the crystal growth device can be controlled to be equalized, and accordingly, the thermal convection can be effectively prevented from occurring in the upstream portion of the reaction tube.

Hence, the raw material gases can be suppressed from flowing back to the upstream portion of the reaction tube, and accordingly, such a defect can be prevented that the reaction tube is broken by the adherence of the GaN-based semiconductor crystal onto the wall surface of the upstream portion of the reaction tube. Moreover, the raw material gases are stably supplied onto the underlying substrate, and accordingly, the good-quality GaN-based semiconductor single crystal can be grown.

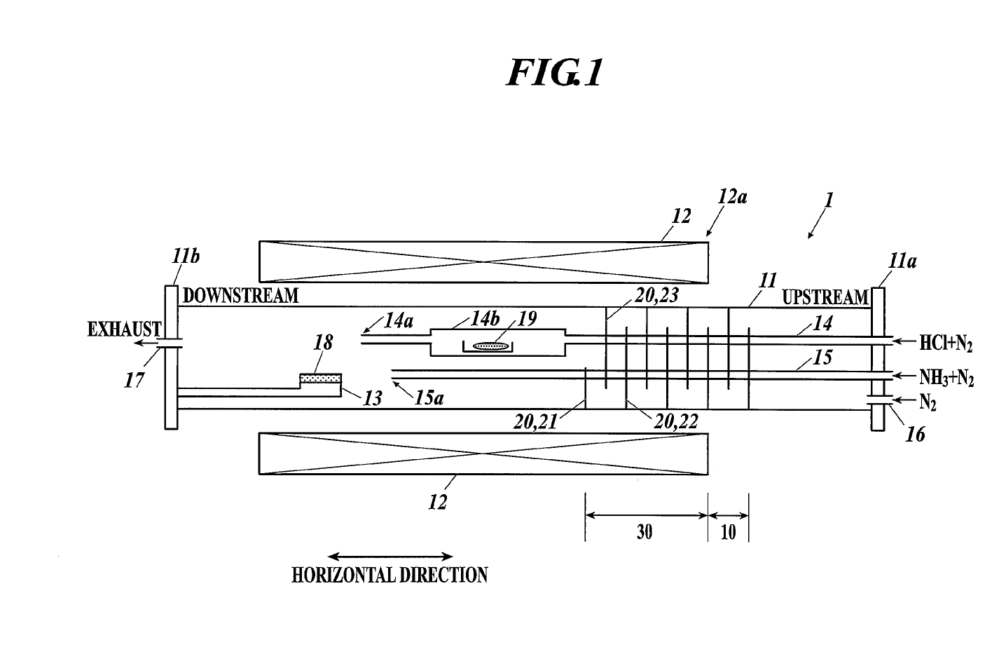

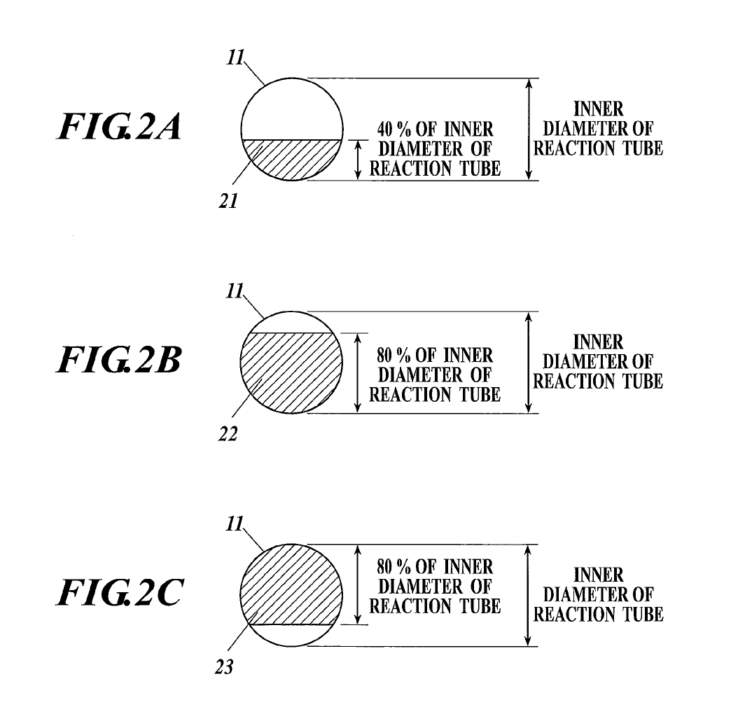

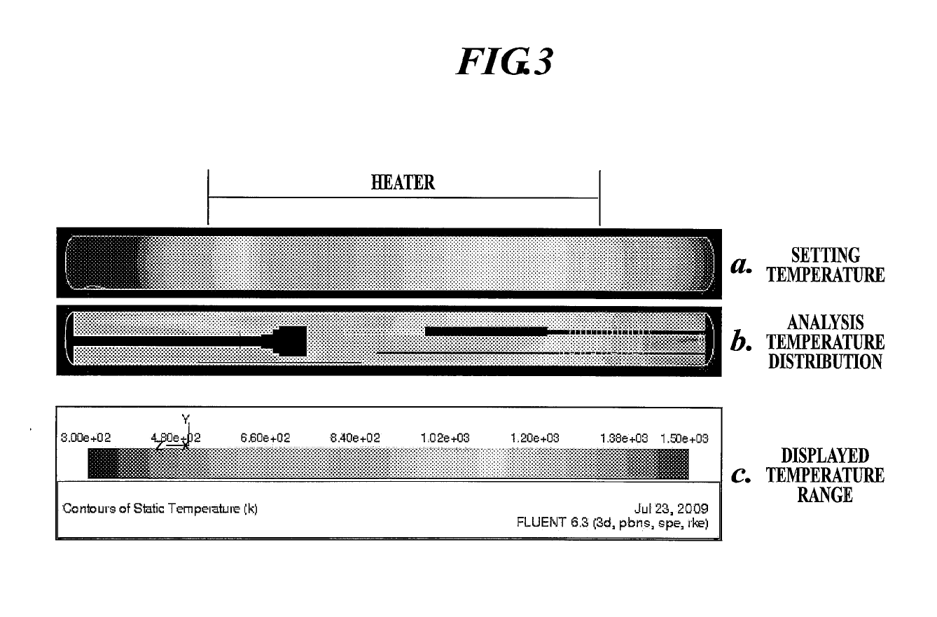

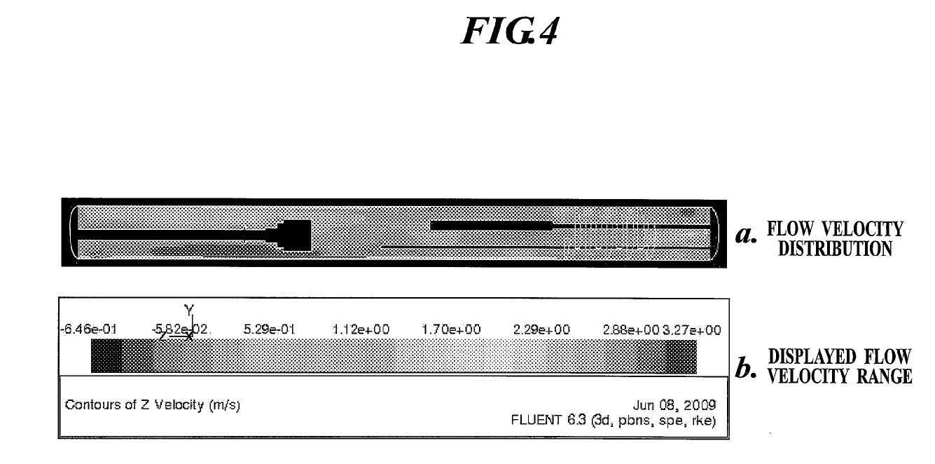

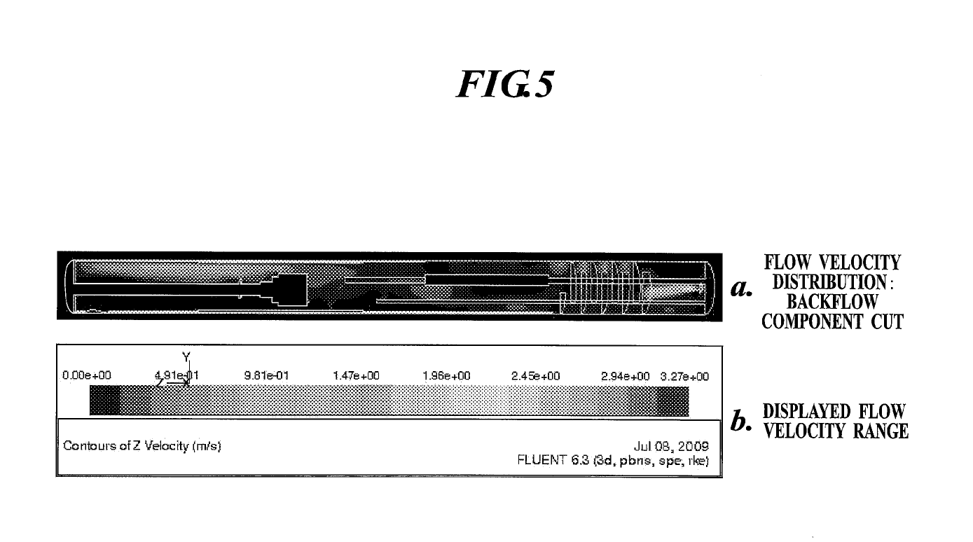

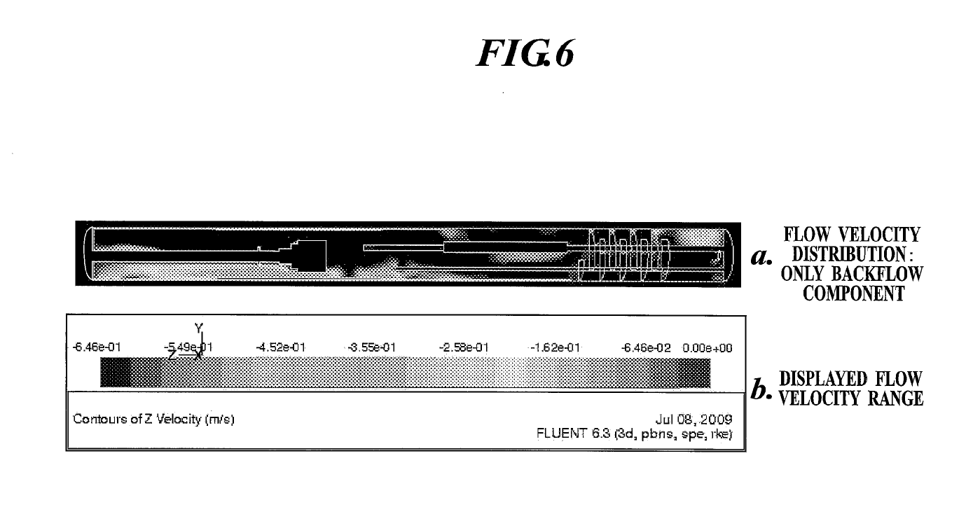

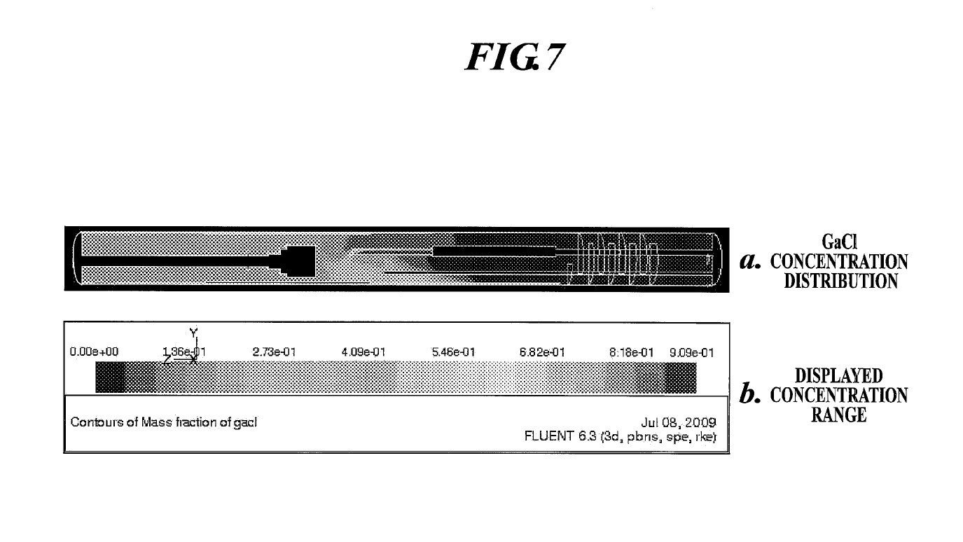

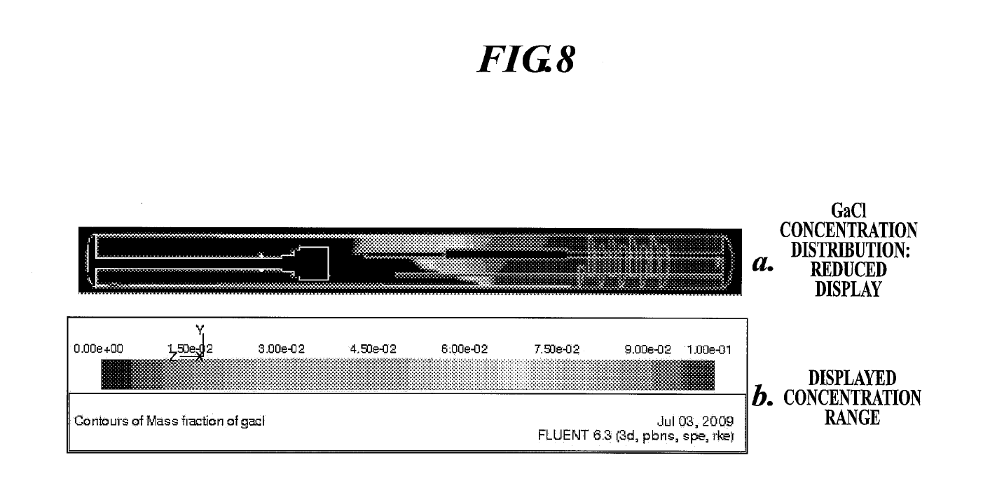

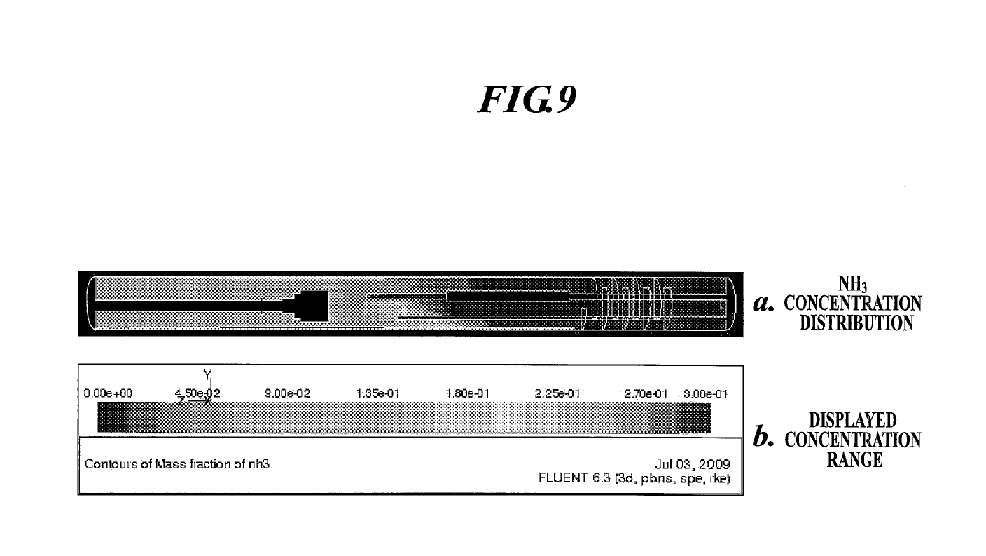

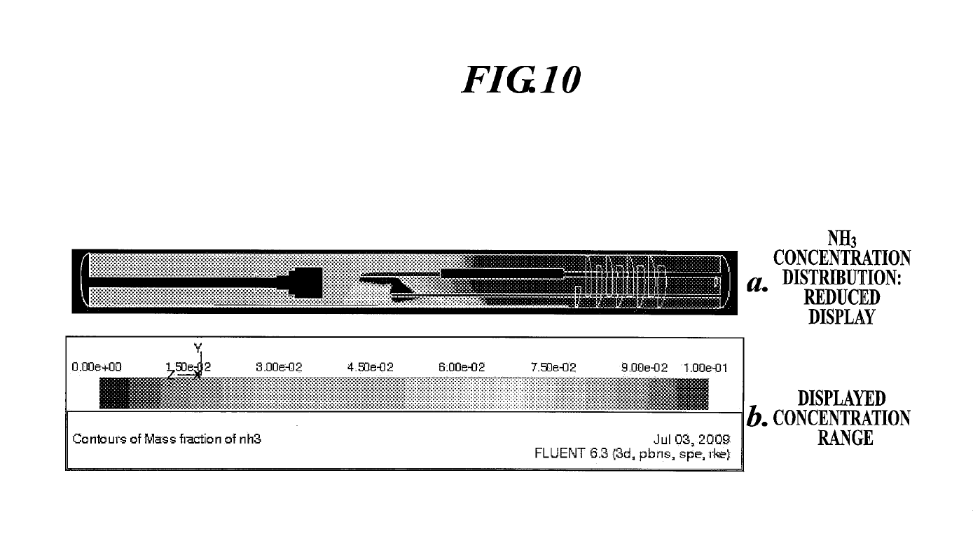

### BRIEF DESCRIPTION OF THE DRAWINGS

[FIG. 1] This is a view showing a schematic configuration of a horizontal-type HVPE device according to an embodiment.

[FIG. 2A] This is a view showing a shape of a partition plate located on a lowermost-stream side.

[FIG. 2B] This is a view showing a shape of a partition plate located upstream of the partition plate of FIG. 2A.

[FIG. 2C] This is a view showing a shape of a partition plate located between the partition plates of FIG. 2A and FIG. 2B.

[FIG. 3] This is a view showing a setting temperature of a reaction tube and an analysis result of a temperature distribution in the reaction tube.

[FIG. 4] This is a view showing a flow velocity distribution in the Z-direction in the reaction tube.

[FIG. 5] This is a view showing a flow velocity distribution (where a backflow component is not shown) in the Z-direction in the reaction tube.

[FIG. 6] This is a view showing a flow velocity distribution (of only the backflow component) in the Z-direction in the reaction tube.

[FIG. 7] This is a view showing a concentration distribution of GaCl in the reaction tube.

[FIG. 8] This is a view showing the concentration distribution (in compact display) of Gad in the reaction tube.

[FIG. 9] This is a view showing concentration distribution of NH₃ in the reaction tube.

[FIG. 10] This is a view showing the concentration distribution (in compact display) of NH₃ in the reaction tube.

[FIG. 11] This is a view showing a schematic configuration of a conventional horizontal-type HVPE device.

[FIG. 12] This is a view showing a setting temperature of a reaction tube and an analysis result of a temperature distribution in the reaction tube according to an analysis model.

[FIG. 13] This is a view showing a flow velocity distribution in the Z-direction in the reaction tube according to the analysis model.

[FIG. 14] This is a view showing a flow velocity distribution (where a backflow component is not shown) in the Z-direction in the reaction tube according to the analysis model.

[FIG. 15] This is a view showing a flow velocity distribution (of only the backflow component) in the Z-direction in the reaction tube according to the analysis model.

[FIG. 16] This is a view showing a concentration distribution of GaCl in the reaction tube according to the analysis model.

[FIG. 17] This is a view showing the concentration distribution (in compact display) of GaCl in the reaction tube according to the analysis model.

[FIG. 18] This is a view showing a concentration distribution of NH₃ in the reaction tube according to the analysis model.

[FIG. 19] This is a view showing the concentration distribution (in compact display) of NH₃ in the reaction tube according to the analysis model.

### MODES FOR CARRYING OUT THE INVENTION

A description is made below in detail of an embodiment of the present invention.

FIG. 1 is a view showing a schematic configuration of a horizontal-type HVPE device according to the embodiment.

As shown in FIG. 1, such an HVPE device 1 includes: a quartz-made reaction tube 11, a heater 12 arranged around the reaction tube 11; a substrate holder 13 that mounts an underlying substrate 18 thereon; a III-group raw material gas supply pipe 14 for supplying III-group raw material gas to a vicinity of the underlying substrate 18; and a V-group raw material gas supply pipe 15 for supplying V-group raw material gas to the vicinity of the underlying substrate 18. Moreover, in a flange 11a on an upstream portion (raw material gas supply side) of the reaction tube 11, a carrier gas introduction port 16 for introducing carrier gas is provided, and in a flange 11b on a downstream portion (underlying substrate side) thereof, an exhaust port 17 for exhausting residual gas is provided. For the carrier gas, N₂, H₂ or mixed gas of both thereof is used. The above-descried configuration is similar to that of the conventional HVPE device 5 shown in FIG. 11.

Moreover, in the HVPE device 1, nine partition plates 20 which partition the reaction tube 11 in an axial direction are provided between the upstream flange 11a and the substrate holder 13. The raw material gas supply pipes 14 and 15 are inserted through these partition plates.

Here, the partition plates 20 (21 to 23) are made of quarts for example, and as shown in FIGS. 1 and 2, are composed of notched disks in each of which a part is notched so as to be even. Then, the partition plates 20 are arranged in parallel to one another so that notched portions can be located alternately in the vertical direction to thereby form a space in the reaction tube 11 into a meandering shape, that is, so that the gases cannot freely pass through the space in the reaction tube 11 by the notched portions of the adjacent partition plates.

Moreover, while taking, as a reference, an upstream side end portion 12a of the heater 12, the partition plates 20 are arranged at an interval of 5 cm in a range from a distance of outside 10 cm to a distance of inside 30 cm.

Furthermore, with respect to the reaction tube 11, a height of the partition plate 21 located on a lowermost-stream side is set at 40% of an inner diameter of the reaction tube (refer to FIG. 2A), and a height of the other partition plates 22 and 23 is set at 80% of the inner diameter of the reaction tube (refer to FIG. 2B and FIG. 2C). The reason why the height of the partition plate 21 is set lower in comparison with the height of the other partition plates 22 and 23 is that convection is to be prevented from occurring in a vicinity of the partition plate 21.

Note that the forms of the above-mentioned partition plates are merely examples, and the forms just need to be those which can equalize a temperature distribution of the upstream portion of the reaction tube 11.

For example, desirably, the height of the partition plate 21 located on the lowermost-stream side is set at a height at which less than 50% of an inner-diameter cross section of the reaction tube 11 is closed. In such a way, the convention can be effectively prevented from occurring in the vicinity of the partition plate 21.

Desirably, the height of the partition plates 22 and 23 is set at a height at which 60 to 80% of the inner-diameter cross section of the reaction tube 11 is closed. In such a way, the temperature distribution of the upstream portion of the reaction tube 11 can be efficiently equalized.

Desirably, the interval between the partition plates 21 to 23 is set at from 1 cm or more to 20 cm or less. In such a way, the temperature distribution of the upstream portion of the reaction tube 11 can be equalized more efficiently.

Desirably, the partition plates 20 are arranged between a spot outside from the heater upstream side end portion 12a by a length of 60% of an effective inner diameter of the heater 12 and a spot apart upstream by 10 cm from an installed position (substrate holder 13) of the underlying substrate. In the embodiment, the effective inner diameter of the heater 12 is 17 cm, and accordingly, while taking the upstream side end portion 12a of the heater 12 as a reference, the partition plates 20 are arranged in the range from the distance of outside 10 cm (60% of the effective inner diameter of the heater 12) to the distance of inside 30 cm. In such a way, the temperature distribution of the upstream portion of the reaction tube 11 can be equalized without inhibiting mixture of the raw material gases.

Furthermore, the number of partition plates 20 to be arranged in the reaction tube 11 is not limited to nine, and may be two to an extreme.

### Simulation by HVPE Device of Embodiment

An analysis model obtained by modeling the HVPE device 1 shown in FIG. 1 for analysis was made, a thermal fluid analysis simulation for the inside of the reaction tube 11 of the HVPE device 1 according to the embodiment was performed, and flows of the gases in the reaction tube 11 were analyzed. Analysis conditions were set similarly to those of the above-mentioned [Simulation by conventional HVPE device].

### Analysis Results of Temperatures

FIG. 3 is a view showing a setting temperature of the reaction tube 11 and an analysis result of the temperature distribution in the reaction tube 11. A displayed temperature range of FIG. 3(c) shows that the temperature is lower on a left gradation, and that the temperature is higher on a right gradation.

As shown in FIG. 3(b), the N₂ carrier gas supplied from the upstream was warmed by the heater 12 during a period while passing through the partition plates 20, and such a result was obtained that an equalized temperature distribution was achieved in the upstream portion.

### Analysis Results of Flows

FIGS. 4 to 6 are views showing flow velocity distributions in the Z-direction in the reaction tube 11. In FIG. 5, a backflow component of FIG. 4 is not shown, and in FIG. 6, only the backflow component of FIG. 4 is shown. In FIGS. 4 and 6, portions in which numbers on bars representing displayed flow velocity ranges become negative show that the gas flows back (from the downstream to the upstream). The displayed flow velocity ranges of FIG. 4(b), FIG. 5(b) and FIG. 6(b) show that the flow velocity is slower (or a backflow velocity is faster) on left gradations, and that the flow velocity is faster (or the backflow velocity is slower) on right gradations. In FIG. 5, the backflow component of FIG. 4 is not displayed, and accordingly, a flow velocity on a left end of FIG. 5(b) is zero. In FIG. 6 only the backflow component of FIG. 4 is displayed, and accordingly, a flow velocity on a right end of FIG. 6(b) is zero. Moreover, a black region (region that is not represented by the gradations of FIG. 5(b)) in FIG. 5(a) is shown to be a backflow region, and a black region (region that is not represented by the gradations of FIG. 6(b)) in FIG. 6(a) is shown to be a downflow region.

As shown in FIGS. 4 and 6, the plurality of partition plates 20 were arranged, whereby such a result was obtained that the backflow of the raw material gases was reduced to a large extent in comparison with that of the analysis results (refer to FIGS. 13 to 15) by the conventional HVPE device.

### Analysis Results of Raw Material Concentration Distributions

FIGS. 7 and 8 are views showing concentration distributions of GaCl in the reaction tube 11. FIG. 8 shows an analysis result in which a range of a displayed concentration is reduced. Each of displayed concentration ranges of FIG. 7(b) and FIG. 8(b) shows that, while taking a left-end concentration as zero, the concentration is lower on a left gradation, and the concentration is higher on a right gradation. Moreover, a black region (region that is not represented by the gradations of FIG. 8(b)) in FIG. 8(a) is shown to be a region with a higher concentration.

As shown in FIGS. 7 and 8, such a result was obtained that the backflow region of Gad was narrowed in comparison with that of the analysis results (refer to FIGS. 16 and 17) by the conventional HVPE device, and did not reach the upstream flange 11a.

FIGS. 9 and 10 are views showing concentration distributions of NH₃ in the reaction tube 11. FIG. 10 shows an analysis result in which a range of a displayed concentration is reduced. Each of displayed concentration ranges of FIG. 9(b) and FIG. 10(b) shows that, while taking a left-end concentration as zero, the concentration is lower on a left gradation, and the concentration is higher on a right gradation. Moreover, a black region (region that is not represented by the gradations of FIG. 10(b)) in FIG. 10(a) is shown to be a region with a higher concentration.

As shown in FIGS. 9 and 10, such a result was obtained that the backflow region of NH₃ was narrowed in comparison with that of the analysis results (refer to FIGS. 18 and 19) by the conventional HVPE device, and did not reach the upstream flange 11a.

As described above, the plurality of partition plates 20 are arranged on the portions which sandwich the upstream side end portion 12a of the heater 12 in the reaction tube 11, whereby the temperature distribution of the upstream portion of the reaction tube 11 is equalized, and the occurrence of the thermal convection can be prevented. Then, the backflow of the material gases is suppressed, and accordingly, GaN can be prevented from being precipitated on the wall surface of the upstream portion of the reaction tube 11, and in addition, the material gases can be supplied with desired concentrations onto the underlying substrate.

### Example 1

In Example 1, by using the HVPE device 1 according to the embodiment, GaN as a GaN-based semiconductor was epitaxially grown on an NGO substrate made of rare earth perovskite.

In the case of growing a GaN crystal by the HVPE device 1, HCl diluted with the carrier gas is introduced into the III-group raw material gas supply pipe 14, and Ga metal 19 and HCl are reacted with each other, whereby GaCl is generated. This GaCl is transported by the III-group raw material gas supply pipe 14, and is supplied as the III-group raw material gas from a nozzle 14a to the vicinity of the underlying substrate 18. Moreover, NH₃ is transported by the V-group raw material gas supply pipe 15, and is supplied as V-group raw material gas from a nozzle 15a to the vicinity of the underlying substrate 18. Gad and NH₃, which are supplied to the vicinity of the underlying substrate 18, are reacted with each other, whereby the GaN crystal is grown on the underlying substrate 18.

First, the NGO substrate was arranged in the HVPE device 1, and a temperature of the substrate was raised until reaching a first growth temperature (600° C.). Then, GaCl, which was created from the Ga metal and HCl, and would serve as the III-group raw material, and NH₃ that would serve as the V-group raw material were supplied onto the NGO substrate, and a low-temperature protection layer made of GaN was formed to a film thickness of 50 nm. At this time, a supply partial pressure of HCl was set at 2.19×10⁻³ atm, and a supply partial pressure of NH₃ was set at 6.58×10⁻² atm.

Next, such a substrate temperature was raised until reaching a second growth temperature (1000° C.). Then, the raw material gases were supplied onto the low-temperature protection layer, and a GaN thick film layer was formed to a film thickness of 3000 μm. At this time, the supply partial pressure of HCl was set at 2.55×10⁻² atm, and the supply partial pressure of NH₃ was set at 4.63×10⁻² atm.

In the case where the GaN crystal was grown by using the HVPE device 1 in which the plurality of partition plates 20 were arranged in the reaction tube 11, the precipitation of GaN onto the wall surface of the upstream portion of the reaction tube 11 was completely eliminated. This is considered to be because, as in the results of the fluid analysis, the backflow of the raw material gases to the upstream portion was eliminated by the partition plates 20.

The obtained GaN crystal was a transparent single crystal, in which a black polycrystal portion was 25% or less of the whole of a growth area. Moreover, an X-ray half-width of the GaN crystal was 500 seconds, and a dislocation density thereof by scanning electron microscopy cathodoluminescence (SEM-CL) was 2×10⁷ cm⁻².

### Example 2

In Example 2, a GaN crystal was epitaxially grown by using the HVPE device 1 according to the embodiment. Example 2 is different from Example 1 in that growth conditions (supply partial pressures of the raw material gases) for the GaN thick film layer are optimized.

Specifically, the low-temperature protection layer was grown similarly to that in Example 1, and at the time of growing the GaN thick film layer, the supply partial pressure of HCl was set at 3.01×10⁻² atm, and the supply partial pressure of NH₃ was set at 7.87×10⁻² atm.

A state of the reaction tube 11 after growing the GaN crystal was similar to that in Example 1, and the precipitation of GaN onto the wall surface of the upstream portion of the reaction tube 11 was not observed. Moreover, the obtained GaN crystal was a transparent single crystal, in which a black polycrystal portion was 25% or less of the whole of a growth area. Moreover, an X-ray half-width of the GaN crystal was 60 seconds, and a dislocation density thereof by the SEM-CL was 1×10⁶ cm⁻². Furthermore, variations of offset angles in the [1-100] direction and [11-20] direction of the GaN thick film layer were 0.11° and 0.12°, respectively.

As described in Examples 1 and 2, the partition plates 20 were arranged in a predetermined region in the reaction tube 11, whereby the raw material gases were able to be prevented from flowing back to the upstream portion of the reaction tube 11, and in such a way, there was eliminated the precipitation of GaN onto the wall surface of the upstream portion of the reaction tube 11 after the growth of the GaN crystal. Moreover, it became possible to supply the raw material gases with desired concentrations onto the underlying substrate, and a high-quality GaN single crystal was obtained with good reproducibility.

### Comparative Example 1

In Comparative example 1, by using the conventional HVPE device 5 (refer to FIG. 11), a GaN crystal was grown under similar growth conditions to those in Example 1.

In the reaction tube 11 after the GaN crystal was grown, GaN was precipitated on the wall surface of the upstream portion. Moreover, the obtained GaN crystal was a black polycrystal, in which an X-ray half-width was 3500 seconds. Moreover, though calculation of a dislocation density of the GaN crystal was attempted by using the SEM-CL, a CL image was not able to be obtained since CL intensity thereof was extremely small, and even the estimation of the dislocation density was impossible.

### Comparative Example 2

In Comparative example 2, by using the conventional HVPE device 5, a GaN crystal was epitaxially grown. Comparative example 2 is different from Comparative example 1 in growth condition (supply partial pressure of HCl) of the GaN thick film layer. Specifically, the low-temperature protection layer was grown in a similar way to that in Comparative example 1, and at the time of growing a GaN thick film layer, the supply partial pressure of HCl was set at 1.16×10⁻² atm, and the supply partial pressure of NH₃ was set at 4.63×10⁻² atm.

A state of the reaction tube 11 after growing the GaN crystal was similar to that in Comparative example 1, and GaN was precipitated on the wall surface of the upstream portion of the reaction tube 11. Moreover, the obtained GaN crystal was a black polycrystal, in which an X-ray half-width was 4000 seconds. Though calculation of a dislocation density of the GaN crystal was attempted by using the SEM-CL, a CL image was not able to be obtained since CL intensity thereof was extremely small, and even the estimation of the dislocation density was impossible.

### Comparative Example 3

In Comparative example 3, by using the conventional HVPE device 5, a GaN crystal was epitaxially grown. Comparative example 3 is different from Comparative example 1 in growth condition (supply partial pressure of NH₃) of the GaN thick film layer. Specifically, the low-temperature protection layer was grown in a similar way to that in Comparative example 1, and at the time of growing the GaN thick film layer, the supply partial pressure of HCl was set at 2.55×10⁻² atm, and the supply partial pressure of NH₃ was set at 9.26×10⁻² atm.

A state of the reaction tube 11 after growing the GaN crystal was similar to that in Comparative example 1, and GaN was precipitated on the wall surface of the upstream portion of the reaction tube 11. Moreover, the obtained GaN crystal was a black polycrystal, in which an X-ray half-width was 4000 seconds. Though calculation of a dislocation density of the GaN crystal was attempted by using the SEM-CL, a CL image was not able to be obtained since CL intensity thereof was extremely small, and even the estimation of the dislocation density was impossible.

As described in each of Comparative examples 1 to 3, in the HVPE device 5 in which the partition plates were not installed in the reaction tube 11, GaN was precipitated on the wall surface of the upper portion of the reaction tube 11 after the GaN crystal was grown, and the obtained GaN was entirely the polycrystal. Moreover, a difference was not observed among the experimental results even if the growth conditions were changed. Accordingly, it is considered that, since the raw material gases flowed back in the reaction tube 11, the concentrations (supply amounts and supply ratio) of the raw material gases supplied onto the underlying substrate were not able to be controlled, and the quality of the GaN crystal was not able to be controlled.

As mentioned above, in accordance with the HVPE device 1 according to the embodiment, a configuration is adopted, in which the plurality of partition plates 20 are provided in the reaction tube 11. In such a way, the temperature distribution in the upstream portion in the reaction tube 11 can be evenly controlled, and accordingly, the thermal convection can be effectively prevented from occurring in the upstream portion of the reaction tube 11.

Hence, the raw material gases can be suppressed from flowing back to the upstream portion of the reaction tube 11, and accordingly, such a defect can be prevented that the reaction tube 11 is broken by the adherence of the GaN-based semiconductor crystal onto the wall surface of the upstream portion of the reaction tube 11. Moreover, the raw material gases are stably supplied onto the underlying substrate, and accordingly, the good-quality GaN-based semiconductor single crystal can be grown.

Based on the embodiment, the description has been specifically made above of the invention made by the inventor of the present invention; however, the present invention is not limited to the above-described embodiment, and is modifiable within the scope without departing from the spirit thereof.

For example, in the above embodiment, the description has been made of the HVPE device for growing the GaN crystal on the underlying substrate; however, the present invention can be applied to an HVPE device for growing other nitride-based compound semiconductor crystals. Here, the nitride-based compound semiconductors are a compound semiconductors represented by InₓGa_{y}Al_{1-x-y}N (0≦x, y≦1, 0≦x≦1, 0≦y≦1), which include, for example, GaN, InGaN, AlGaN, InGaAlN and the like. Note that, in the case of growing a nitride-based compound semiconductor crystal containing two or more III-group elements, a plurality of the III-group raw material gas supply pipes are provided.

It should be considered that the embodiment disclosed this time is illustrative and not restrictive in all of points. The scope of the present invention is shown not by the above description but by the scope of claims, and it is intended that all modifications within the meaning and the scope, which are equivalent to the scope of claims, are included in the present invention.

### EXPLANATION OF REFERENCE NUMERALS

1 HVPE DEVICE (CRYSTAL GROWTH DEVICE)

11 REACTION TUBE

11a UPSTREAM FLANGE

11b DOWNSTREAM FLANGE

12 HEATER

13 SUBSTRATE HOLDER

14 III-GROUP RAW MATERIAL GAS SUPPLY PIPE

15 V-GROUP RAW MATERIAL GAS SUPPLY PIPE

16 CARRIER GAS INTRODUCTION PORT

17 EXHAUST PORT

18 UNDERLYING SUBSTRATE

19 Ga METAL

20 TO 23 PARTITION PLATE

1. A horizontal-type crystal growth device, in which,
in a reaction tube, there are arranged:
a substrate holder that holds an underlying substrate;
a raw material gas supply pipe that supplies raw material gas to a vicinity of the underlying substrate; and
a carrier gas introduction port that introduces carrier gas into the reaction tube,
a cylindrical heater that heats the substrate holder and a vicinity of an opening end of the raw material gas supply pipe is arranged around the reaction tube, and
a nitride-based compound semiconductor crystal is grown on the underlying substrate by using hydride vapor phase epitaxy,
wherein a plurality of partition plates which partition the reaction tube in an axial direction are provided between an end portion of the reaction tube on a side where the raw material gas supply pipe is arranged and an installed position of the underlying substrate.

2. The crystal growth device according to claim 1, wherein the plurality of partition plates are notched disks in each of which a part is notched, and are arranged in parallel to one another so that notched portions are located alternately in a vertical direction to form a space in the reaction tube into a meandering shape.

3. The crystal growth device according to claim 2, wherein the plurality of partition plates are arranged at an interval of 1 cm or more to 20 cm or less.

4. The crystal growth device according to claim 2, wherein the plurality of partition plates excluding a first piece of the plates arranged on an installed position side of the underlying substrate close 60 to 80% of an inner-diameter cross section of the reaction tube.

5. The crystal growth device according to claim 2, wherein, among the plurality of partition plates, the first piece arranged on the installed position side of the underlying substrate closes less than 50% of the inner-diameter cross section of the reaction tube.

6. The crystal growth device according to claim 1, wherein the plurality of partition plates are arranged between a spot outside from an upstream side end portion of the heater by a length of 60% of an effective inner diameter of the heater and a spot apart upstream by 10 cm from the installed position of the underlying substrate.

7. A production method of the nitride-based compound semiconductor crystal, wherein the nitride-based compound semiconductor crystal is grown on the underlying substrate by using the crystal growth device according to claim 1.

8. The production method of the nitride-based compound semiconductor crystal according to claim 7, wherein the underlying substrate is an NGO substrate.

9. The nitride-based compound semiconductor crystal obtained by the production method according to claim 7,
wherein a polycrystal portion is 25% or less of a whole of a growth area.

10. The crystal growth device according to claim 3, wherein the plurality of partition plates excluding a first piece of the plates arranged on an installed position side of the underlying substrate close 60 to 80% of an inner-diameter cross section of the reaction tube.

11. The crystal growth device according to claim 3, wherein, among the plurality of partition plates, the first piece arranged on the installed position side of the underlying substrate closes less than 50% of the inner-diameter cross section of the reaction tube.

12. The crystal growth device according to claim 4, wherein, among the plurality of partition plates, the first piece arranged on the installed position side of the underlying substrate closes less than 50% of the inner-diameter cross section of the reaction tube.

13. The crystal growth device according to claim 2, wherein the plurality of partition plates are arranged between a spot outside from an upstream side end portion of the heater by a length of 60% of an effective inner diameter of the heater and a spot apart upstream by 10 cm from the installed position of the underlying substrate.

14. The crystal growth device according to claim 3, wherein the plurality of partition plates are arranged between a spot outside from an upstream side end portion of the heater by a length of 60% of an effective inner diameter of the heater and a spot apart upstream by 10 cm from the installed position of the underlying substrate.

15. The crystal growth device according to claim 4, wherein the plurality of partition plates are arranged between a spot outside from an upstream side end portion of the heater by a length of 60% of an effective inner diameter of the heater and a spot apart upstream by 10 cm from the installed position of the underlying substrate.

16. The crystal growth device according to claim 5, wherein the plurality of partition plates are arranged between a spot outside from an upstream side end portion of the heater by a length of 60% of an effective inner diameter of the heater and a spot apart upstream by 10 cm from the installed position of the underlying substrate.

17. A production method of the nitride-based compound semiconductor crystal, wherein the nitride-based compound semiconductor crystal is grown on the underlying substrate by using the crystal growth device according to claim 2.

18. A production method of the nitride-based compound semiconductor crystal, wherein the nitride-based compound semiconductor crystal is grown on the underlying substrate by using the crystal growth device according to claim 3.

19. A production method of the nitride-based compound semiconductor crystal, wherein the nitride-based compound semiconductor crystal is grown on the underlying substrate by using the crystal growth device according to claim 4.

20. A production method of the nitride-based compound semiconductor crystal, wherein the nitride-based compound semiconductor crystal is grown on the underlying substrate by using the crystal growth device according to claim 5.
